(19) United States
(12) Patent Application Publication
(10) Pub. No.: US 2019/0181131 A1
(43) Pub. Date: Jun. 13, 2019

(54) ELECTRONIC DEVICE OF PROTECTION AGAINST ELECTROSTATIC DISCHARGES

(71) Applicant: STMicroelectronics SA, Montrouge (FR)

(72) Inventors: Philippe GALY, Le Touvet (FR); Louise DE CONTI, Grenoble (FR)

(73) Assignee: STMicroelectronics SA, Montrouge (FR)

(21) Appl. No.: 16/216,541

(22) Filed: Dec. 11, 2018

(30) Foreign Application Priority Data
Dec. 13, 2017 (FR) 1762078

(51) Int. Cl. H01L 27/02; H02H 9/04

(52) U.S. Cl. CPC H01L 27/027; H02H 9/046

(57) ABSTRACT

An electronic device for providing ESD protection is formed by a MOS transistor. the MOS transistor includes a source region and a drain region that are separated from each other by a channel-forming region. A first gate is located over the channel forming region. The drain region includes an extension region. A second gate is located over the extension region. The first and second gates are electrically connected to each other.

### PRIORITY CLAIM

This application claims the priority benefit of French Application for Patent No. 1762078, filed on Dec. 13, 2017, the content of which is hereby incorporated by reference in its entirety to the maximum extent allowable by law.

### TECHNICAL FIELD

The present disclosure relates to an electronic device, and more particularly to an electronic device of protection against electrostatic discharges (ESDs).

### BACKGROUND

An electronic component connected between two terminals of application of a voltage may be damaged by an electrostatic discharge on one of the two terminals, such a discharge causing a current pulse due to a pulse voltage difference between the two terminals.

To protect the electronic component from such a discharge, an electronic protection device is connected between the two terminals, in parallel with the component to be protected. Thus, in an electrostatic discharge, the current pulse crosses the electronic protection device, which enables to protect the electronic component.

It would be desirable to have an electronic device of protection against electrostatic discharges which overcomes at least some of the disadvantages of existing devices.

### SUMMARY

An embodiment provides an electronic device comprising a MOS transistor having source and drain regions separated from each other by a channel-forming region topped with a first gate, the drain region comprising an extension topped with a second gate connected to the first gate.

According to an embodiment, the drain and source regions are respectively coupled to first and second terminals of application of a voltage, the device further comprising a resistive element having a first terminal coupled to the second terminal of application of a voltage and having a second terminal coupled to the first gate.

According to an embodiment, the second terminal of the resistive element is further coupled to the channel-forming region.

According to an embodiment, the drain region and its extension are interrupted, under the second gate, by a separation region.

According to an embodiment, the separation region is non-doped or doped with a conductivity type opposite to that of the drain region.

According to an embodiment, the drain region and its extension comprise two portions extending from opposite sides of the separation region.

According to an embodiment, the two portions of the drain region and of its extension are coupled together.

According to an embodiment, the separation region and the channel-forming region are coupled together.

According to an embodiment, the drain region, the extension of the drain region and the source region of the MOS transistor are doped with a first conductivity type, the channel-forming region being non-doped or doped with a second conductivity type opposite to the first one.

According to an embodiment, the source, drain, and channel-forming regions extend in a semiconductor layer resting on an insulating layer.

According to an embodiment, a portion only of the extension is topped with the second gate.

According to an embodiment, the device further comprises at least another MOS transistor connected in parallel with said MOS transistor.

According to an embodiment, the drain and source regions and the gate of each other MOS transistor are respectively coupled to the drain and source region and to the gates of the MOS transistor comprising the second gate.

According to an embodiment, the body region of each other MOS transistor is coupled to the body region of the MOS transistor comprising the second gate.

### BRIEF DESCRIPTION OF THE DRAWINGS

The foregoing and other features and advantages will be discussed in detail in the following non-limiting description of specific embodiments in connection with the accompanying drawings, wherein:

FIGS. 1A, 1B, and 1C schematically illustrate an embodiment of an electronic device of protection against electrostatic discharges;

FIGS. 2A, 2B, and 2C schematically illustrate an alternative embodiment of the device of FIGS. 1A to 1C;

FIGS. 3A, 3B, and 3C schematically illustrate another alternative embodiment of the device of FIGS. 1A, 1B, and 1C;

FIGS. 4A, 4B, and 4C schematically illustrate another embodiment of a device of protection against electrostatic discharges;

FIG. 5 shows current-vs.-voltage curves illustrating the operation of the devices of FIGS. 2A-2C and 3A-3C; and

FIG. 6 schematically illustrates an embodiment of a device of protection against electrostatic discharges.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed. Although the case where a component to be protected and a device of protection against electrostatic discharges are connected in parallel between two terminals of application of a power supply voltage has been described, the two terminals may also correspond to two input terminals of the component intended to receive an input voltage of this component, or to two output terminals of the component intended to supply an output voltage of this component.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings. Unless otherwise specified, term “approximately” and expression “in the order of” means to within 10%, preferably to within 5%.

Unless otherwise specified, when reference is made to two elements connected together, this means that the elements are directly connected with no intermediate element other than conductors, and when reference is made to two elements coupled together, this means that the two elements may be directly coupled (connected) or coupled via one or a plurality of other elements.

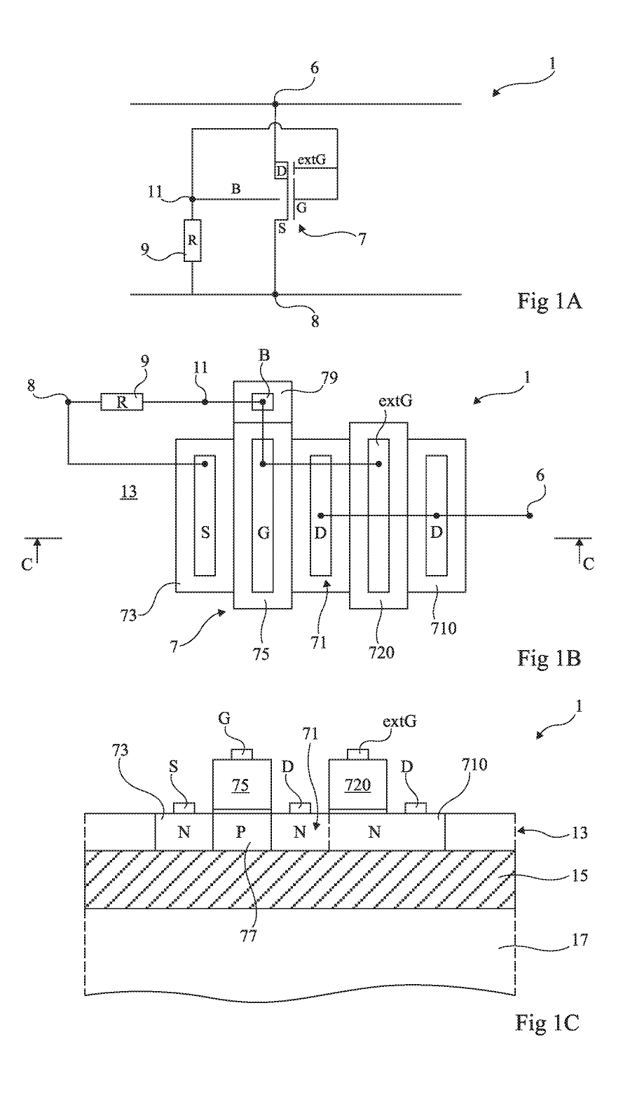

FIGS. 1A to 1C schematically illustrate an embodiment of a device 1 of protection against electrostatic discharges. FIG. 1A is an electric diagram of the circuit of device 1. FIG. 1B is a simplified top view of device 1. FIG. 1C is a cross-section view along plane CC of FIG. 1B, and the various electric connections are not shown in FIG. 1C.

Device 1 aims at protecting an electronic component (not shown) connected between two terminals 6 and 8 intended to receive a power supply voltage, for example, a positive voltage at terminal 6 which is referenced to terminal 8, typically the ground, this voltage being for example a DC voltage.

Device 1 comprises a MOS transistor 7, here an N-channel MOS transistor, and a resistive element 9 (R). Drain region D (71 in FIGS. 1B and 1C) of transistor 7, for example, N-type doped, is coupled, preferably connected, to terminal 6. Source region S (73 in FIGS. 1B and 1C) of transistor 7, for example, N-type doped, is coupled, preferably connected, to terminal 8. Gate G (75 in FIGS. 1B and 1C) of transistor 7 rests on a channel-forming region 77 extending between source region 73 and drain region 71 and separating them from each other, region 77 being for example P-type doped or non-doped. Gate 75 is coupled, preferably connected, to body B of transistor 7 and to a terminal 11 of resistive element 9, the other terminal of the resistive element being coupled, preferably connected, to terminal 8. In the shown example, regions 71, 73, and 77 correspond to portions of a semiconductor layer 13 of SOI type resting on an insulating layer 15, itself arranged on a support 17, for example, a semiconductor substrate. In this example, body B of transistor 7 corresponds to channel-forming region 77 which may then comprise a portion 79 arranged beyond source and drain regions 73 and 71 to form a contacting region coupled, preferably connected, to gate 75 and to terminal 11.

According to the shown embodiment, drain 71 comprises a lateral extension 710 (indicated with dotted lines in FIG. 1C), on the side opposite to region 77. Extension 710 is doped with the same conductivity type as the drain, for example, with the same doping level. An additional gate extG (720 in FIGS. 1B and 1C) coupled, preferably connected, to gate 75 rests on a portion of extension 710 of drain 71. As shown herein as an example, additional gate 720 is separate from gate 75. In the shown example, drain 71 is coupled to terminal 6 via a drain contact D arranged between gates 75 and 720 and a drain contact D arranged on extension 710 of drain 71, on the side of additional gate 720 opposite to gate 75. As a variation, a single drain contact D is provided and is arranged between gates 75 and 720, or on the side of gate 720 opposite to gate 75.

Device 1 takes advantage of the parasitic bipolar transistor of transistor 7, the parasitic bipolar transistor being formed by the source, drain, and body regions of the MOS transistor. When MOS transistor 7 is configured so that its gate is biased with a voltage smaller than its threshold voltage and so that the voltage different between body B and the source is positive, the effect of the parasitic bipolar transistor can be observed.

An electrostatic discharge causes a short current pulse, typically of a few microseconds, having a voltage peak which is for example in the order of two amperes and generally occurs after a few nanoseconds, for example, 10 nanoseconds. An electrostatic discharge generated by the human body may for example be modeled by a HBM (“Human Body Model”) circuit, and then corresponds to a pulse discharge through a R-L-C circuit having a voltage peak which occurs after a few nanoseconds, for example, 10 nanoseconds, with an intensity from 1 to 4 Kvolts HBM. The response of a protection device to an electrostatic discharge can be simulated by using the ACS (“Average Current Slope”) method and/or the AVS (“Average Voltage Slope”) method, well known by those skilled in the art. When an electrostatic discharge occurs on terminal 6, it is transmitted to terminal 11 via drain-gate capacitor CDG of transistor 7 and via drain-body capacitor CDB of transistor 7. The current pulse through capacitors CDG and CDB, which are functionally in parallel, is transformed by resistive element 9 into a voltage between terminals 11 and 8. This voltage represents the gate voltage of MOS transistor 7 and sets the current in the parasitic bipolar transistor. The values of capacitances CDB and CDG and the resistance of resistive element 9 thus condition the value of the turn-on threshold of device 1, that is, the amplitude of the electrostatic discharge from which the parasitic bipolar transistor turns on enabling, as a complement to the MOS transistor, to remove the electrostatic discharge. More particularly, a decrease in capacitance CDG and/or in capacitance CDB results in an increase in the turn-on threshold, which may raise a problem.

Additional gate extG introduces, between terminals 6 and 11, in addition to the intrinsic drain-gate capacitance of a single-gate transistor of same dimensions (with no additional gate) as transistor 7, an additional drain-gate capacitor in parallel with this intrinsic drain-gate capacitor. This increase capacitance CDG of transistor 7 as compared with that of a single-gate transistor of same dimensions as transistor 7. This results in a decrease in the turn-on threshold of device 1 with respect to the case where it would be formed with a single-gate transistor of same dimensions as transistor 7.

This is, for example, advantageous in the case where transistor 7 is formed at the same time as single-gate MOS transistors where capacitance CDG has been decreased, and where transistor 7 corresponds to a MOS transistor having a decreased capacitance CDG, to which extension 710 of drain 71, additional gate 720 and the connection thereof to gate 75, have been added. Indeed, without such a specific structure of transistor 7, the turn-on threshold of device 1 may be too high to protect an electronic component against an electrostatic discharge.

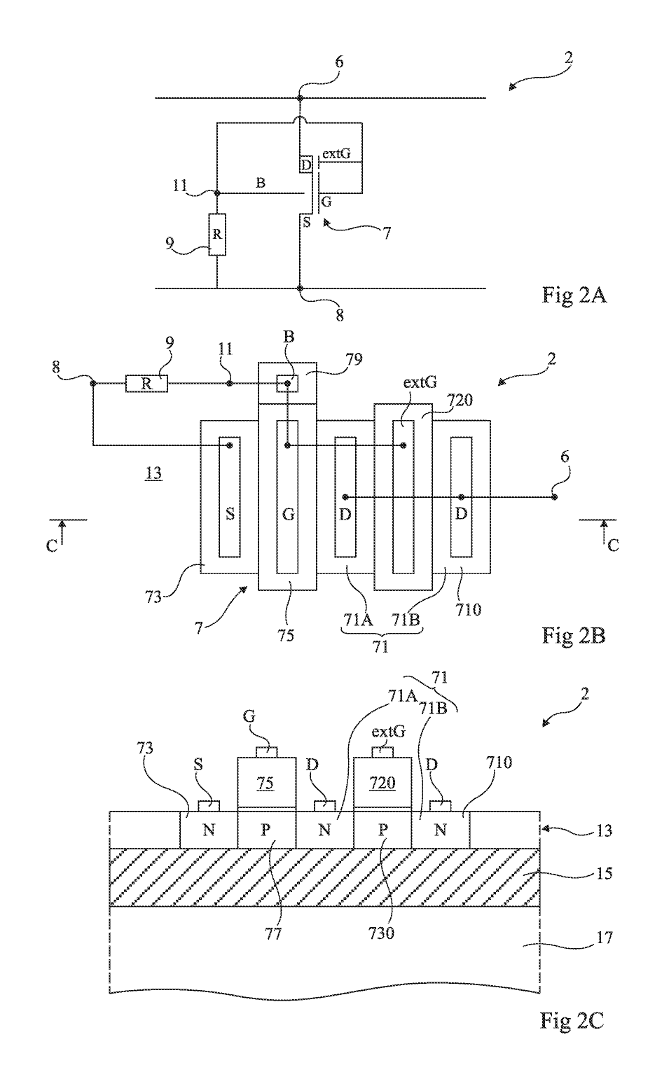

FIGS. 2A to 2C schematically illustrate an alternative embodiment of the device of FIGS. 1A to 1C. FIG. 2A is an electric diagram of the circuit of a device 2 of protection against electrostatic discharges. FIG. 2B is a simplified top view of device 2. FIG. 2C is a cross-section view along plane CC of FIG. 2B, and the various electric connections are not shown in FIG. 2C.

Device 2 is identical to device 1 of FIGS. 1A to 1C, with the difference that drain region 71 and its extension 710 are interrupted, under additional gate 720, by a separation region 730, region 730 being for example doped in the same way as region 77. In the embodiment illustrated herein, drain region 71, which comprises extension 710, then comprises two separate regions 71A and 71B electrically insulated from each other by region 730. For example, region 71A extends between gates 75 and 720, region 71B extending on the side of gate 720 opposite to gate 75. Regions 71A and 71B of drain 71 are coupled, preferably connected, to each other and to terminal 6, a drain contact D being then arranged on each of regions 71A and 71B.

In the same way as for device 1, the provision of additional gate 720 enables to increase capacitance CDG of transistor 7 with respect to that of a single-gate MOS transistor of same dimensions, and thus to decrease the turn-on threshold of device 2 with respect to the case where the latter would be formed with a single-gate transistor of same dimensions as transistor 7.

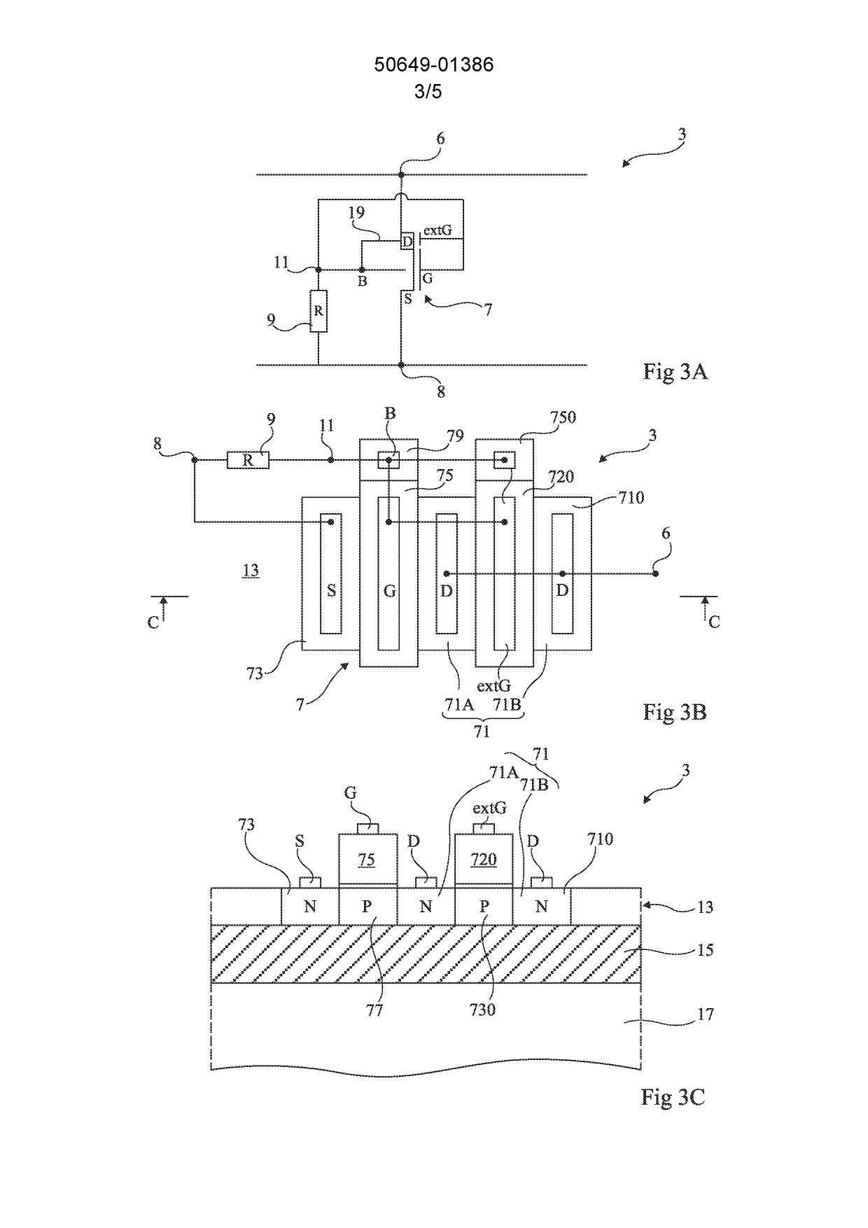

FIGS. 3A to 3C schematically illustrate another alternative embodiment of the device of FIGS. 1A to 1C. FIG. 3A is an electric diagram of the circuit of a device 3 of protection against electrostatic discharges. FIG. 3B is a simplified top view of device 3. FIG. 3C is a cross-section view along plane CC of FIG. 3B, and the various electric connections are not shown in FIG. 3C.

Device 3 is identical to device 2 of FIGS. 2A to 2C with the difference that region 730 is coupled, preferably connected, to body B of transistor 7, here, region 77. In this example, region 730 comprises a portion 750 arranged beyond source region 73 and drain region 71, more particular, here, beyond regions 71A and 71B, to form a contacting region coupled, preferably connected, to body B of transistor 7. This connection is indicated in FIG. 3A by a line 19 starting from body B of transistor 7, and running all the way to the level of additional gate extG.

In the same way as for device 1 or 2, the provision of additional gate 720 enables to increase capacitance CDG of transistor 7 with respect to that of a single-gate MOS transistor of same dimensions, and thus to decrease the turn-on threshold of device 3 with respect to the case where the latter would be formed with a single-gate transistor of same dimensions as transistor 7.

Further, additional gate extG coupled to gate 75 and region 730 coupled to region 77 introduce, between terminals 6 and 11, in addition to the intrinsic drain-gate capacitance of a single-gate transistor of same dimensions as transistor 7, an additional drain-gate capacitor in parallel with the intrinsic drain-gate capacitor. This increase capacitance CDB of transistor 7 as compared with that of a single-gate transistor of same dimensions, which contributes to decreasing the turn-on threshold of device 3 with respect to the case where it would be formed with a single-gate MOS transistor of same dimensions as transistor 7.

This is for example advantageous in the case where transistor 7 is formed inside and on top of a SOI-type layer, the thickness of which has been decreased to decrease the capacitance CDB of single-gate MOS transistors formed, for example, at the same time as transistor 7, inside and on top of the SOI layer. Without such a specific structure of transistor 7, the turn-on threshold of device 3 might have been too high to protect an electronic component against an electrostatic discharge.

In an alternative embodiment, only region 71A is coupled, preferably connected, to terminal 6.

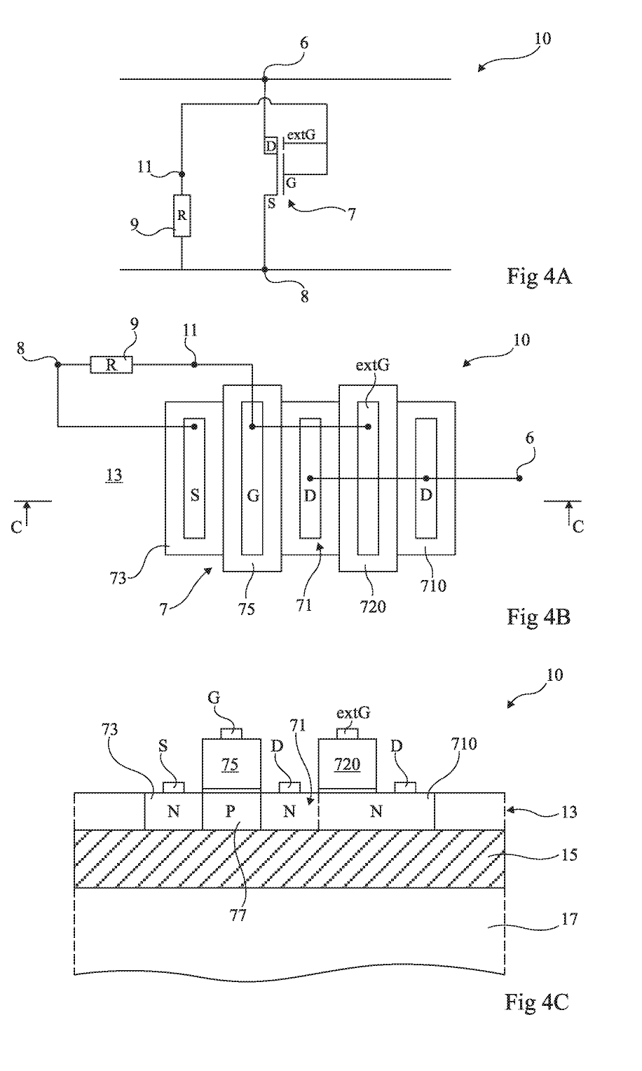

FIGS. 4A, 4B, and 4C schematically illustrate another embodiment of a device 10 of protection against electrostatic discharges. FIG. 4A is an electric diagram of the circuit of device 10. FIG. 4B is a simplified top view of device 10. FIG. 4C is a cross-section view along plane CC of FIG. 4B, and the various electric connections are not shown in FIG. 4C.

As compared with the embodiment of FIGS. 1A to 1C, body region B of transistor 7 of device 10 is not coupled to terminal 11 of resistive element 9. In this case, as shown in FIG. 4B, region 79 may be omitted. The other elements of device 10 are similar to the corresponding elements of device 1 of FIGS. 1A to 1C, these other elements being arranged and coupled together similarly to what has been described for device 1.

In the same way as for device 1, the provision of additional gate extG in device 10 increases capacitance CDG of transistor 7 with respect to that of a single-gate transistor of same dimensions. As a result, a device 10 has a lower turn-on threshold than that of a device 10 where transistor 7 would be replaced with a single-gate MOS transistor having the same dimensions.

The previously-described alternative embodiments of device 1 also apply to the embodiment described hereabove in relation with FIGS. 4A to 4C, body B of transistor 7 then being neither coupled, nor connected to terminal 11 of resistive element 9.

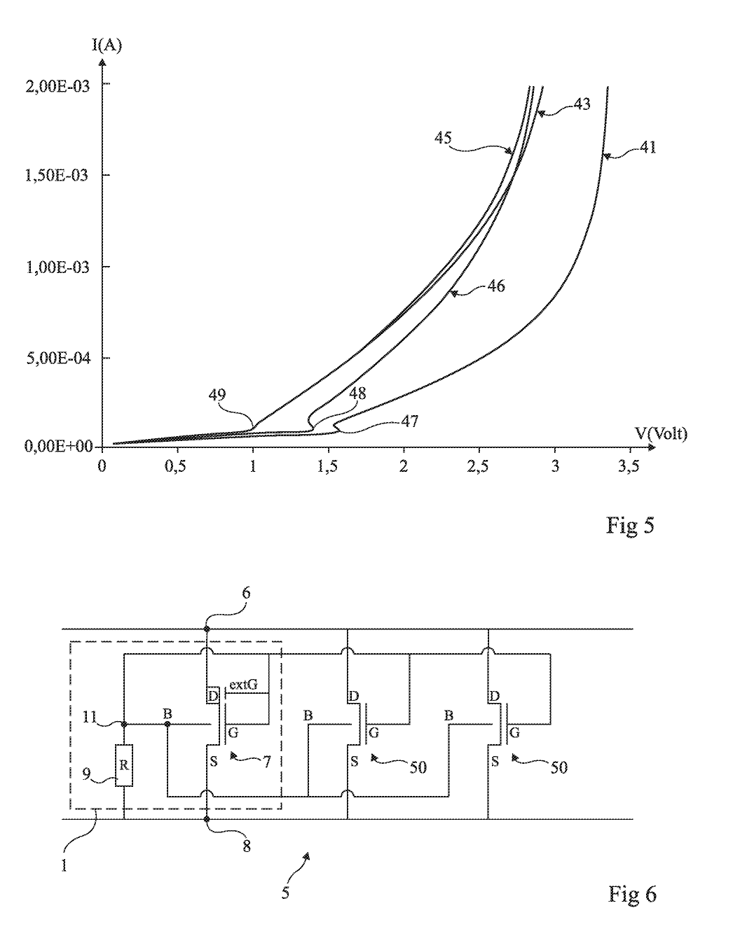

FIG. 5 shows current-vs.-voltage curves 41, 43, 45, and 46. Curve 41 is obtained for a device 1, 2, or 3 where transistor 7 would be replaced with a single-gate transistor having the same dimensions (single-gate device). Curve 43 is obtained for a device 2 with two drain contacts D arranged on either side of additional gate 720, as shown in FIG. 2B. Curve 45 is obtained for a device 3 with a drain contact D on each of regions 71A and 71B, as shown in FIG. 3B. Curve 46 is obtained for a device 1, 2, or 3 where transistor 7 would be replaced with two single-gate transistors of same dimensions as transistor 7, connected in parallel with each other (single-gate device in parallel). In other words, curve 46 is obtained for a device 3 where region 71B would be coupled with terminal 8 rather than with terminal 6. Curves 41, 43, 45, and 46 have been obtained by digital simulation of TCAD (“Technology CAD”) type according to the ACS method and illustrate the variation of current I, in amperes (A), flowing between terminals 6 and 8 of these devices, according to voltage V, in volts, between terminals 6 and 8.

These curves show that the single-gate device and the single-gate device in parallel would have turn-on thresholds, respectively 47 and 48, here approximately 1.6 volt and 1.4 volt respectively, greater than turn-on threshold 49, here approximately 1 volt, of devices 2 and 3.

Further, curves 41, 43, and 45 show that, for a same current value I, devices 2 and 3 enable to limit voltage V between terminals 6 and 8 to a value smaller than that of the voltage between terminals 6 and 8 of a single-gate device.

Curves 45 and 46 show that, for a same current value I, at least up to 2*10⁻³ A (in practice up to 10⁻² A although this is not shown in FIG. 5), voltage V across 6 and 8 of device 3 is smaller than that of a single-gate device in parallel.

Further, curves 43, 45, and 46 show that the on-state resistance of devices 2 and 3 is of the same order of magnitude as that of a single-gate device in parallel. In practice, the on-state resistance of a single-gate device in parallel is smaller than that of a device 2 or 3 due to the fact that a single-gate device in parallel comprises two channel-forming regions where the current can flow, conversely to devices 2 and 3 where the current mainly flows in a single channel-forming region 77. However, devices 2 and 3 have a lower turn-on threshold than that of a single-gate device in parallel, which enables voltage V between terminals 6 and 8 of a device 2 or 3 to be smaller than that between terminals 6 and 8 of a single-gate device in parallel, up to a current I of 1.5*10⁻³ A for device 2 and of 10⁻² A for device 3.

An electronic component is thus more efficiently protected against electrostatic discharges by a device 2 or 3 than by a device 1, 2, or 3 where transistor 7 would be replaced with a single-gate MOS transistor of same dimensions or with two single-gate MOS transistors of same dimensions in parallel with each other.

Digital simulations of TCAD type have shown that the turn-on thresholds of a device 1 comprising two drain contacts arranged on either side of gate 720 or a single drain contact arranged between gates 75 and 720 of a device 2 comprising a single drain contact between gates 75 and 720, and of a device 3 where only region 71A is coupled, preferably connected, to terminal 6, remain smaller than that of a device 1, 2, or 3 where transistor 7 would be replaced with a single-gate MOS transistor of same dimensions or with two single-gate MOS transistors of same dimensions in parallel with each other.

FIG. 6 illustrates an embodiment of a device 5 of protection against electrostatic discharges comprising device 1 of FIGS. 1A, 1B, and 1C. Device 5 has a turn-on threshold corresponding to that of the device 1 that it comprises, and enables to discharge a greater current than if device 1 was used alone.

More particularly, device 5 comprises, in addition to device 1, at least one additional MOS transistor 50, two in this example, connected in parallel with device 1, between terminals 6 and 8. As an example, MOS transistors 50 have, like transistor 7, an N channel.

Each transistor 50 comprises, like transistor 7, a drain D coupled, preferably connected, to terminal 6, a source S coupled, preferably connected, to terminal 8, and a gate G coupled, preferably connected, to terminal 11 of resistive element 9, the body B of each transistor 50, for example corresponding to the channel-forming region of this transistor, being coupled, preferably connected, to terminal 11.

In device 5, during an electrostatic discharge, the turning on of transistors 7 and 50 and of their parasitic bipolar transistors is controlled by the voltage across resistive element 9, and thus by device 1. The presence of at least one transistor 50 in parallel with device 1 then enables to absorb a greater current than if device 1 was used alone. Device 5 is for example particularly adapted to the protection of a component against electrostatic discharges generated by the human body.

Specific embodiments have been described. Various alterations, modifications, and improvements will occur to those skilled in the art. In particular, in a device of the type in FIG. 6, device 1 may be replaced with a device of the type in FIGS. 2A to 2C, of FIGS. 3A to 3C, or of FIGS. 4A to 4C. In the case where body region B of transistor 7 is connected or coupled to terminal 11, it is possible for the body region B of each transistor 50 not to be coupled or connected to terminal 11.

It may be provided that, similarly to drain 71, source 73 of devices 1, 2, 3, and 10 comprises an extension having a portion coated with another additional gate. Source 73 and its extension may be interrupted by a separation region, for example, doped in the same way as region 77, arranged under this other additional gate so that the source comprises two separate portions insulated from each other by this separation region. The separation region interrupting source 73 may then be coupled, preferably connected, to body B of transistor 7 and/or the two portions of source 73 may be connected together.

The previously described embodiments and alternative embodiments are appropriate to the case where a negative voltage is applied between terminals 6 and 8. Further, although embodiments and alternative embodiments where the MOS transistors have an N channel have been described, these embodiments and variations are dually applied to the case where the MOS transistors have a P channel, for example, by inverting all the conductivity types indicated hereabove as an example.

Devices 1, 2, 3, 10 and their alternative embodiments may be used in devices of the type of those of FIGS. 5, 12, 14, 17, 19, 20, 22, 23, 27, and 28 of PCT Patent Application Publication No. WO2011/089179 (incorporated by reference).

Further, although devices 1, 2, 3, and 10 formed inside and on top of an SOI-type layer have been described, the devices and their alternative embodiments may be formed inside and on top of a solid semiconductor substrate, for example, a silicon substrate. In this case, channel-forming region 77 of transistor 7 for example corresponds to a portion of a doped well formed in this substrate, the well then corresponding to body B of transistor 7 and comprising, if present, region 730. Devices 1, 2, 3, 10 and their alternative embodiments may also be formed inside and on top of a hybrid structure where one or a plurality of portions of an insulating layer coated with a semiconductor layer of SOI-type have been etched down to the semiconductor support substrate. Further, although this has not been described, the drain and the source of transistors 7 may comprise epitaxial areas and/or one or a plurality of spacers may be provided on the sides of gate 75 and/or of gate 720.

Although the above-described modes and alternative embodiments have been described for the case where gate 75 and gate 720 are separated from each other, these gates may be non-separated.

Various embodiments with various variations have been described hereabove. It should be noted that those skilled in the art may combine various elements of these various embodiments and variations without showing any inventive step.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An electronic device, comprising:
a first MOS transistor having a source region and a drain region that are separated from each other by a channel-forming region;
a first gate over the channel-forming region;
wherein the drain region comprises an extension region; and
a second gate over the extension region, wherein the second gate is connected to the first gate.

2. The electronic device of claim 1, wherein the drain region and source region are respectively coupled to first and second terminals of application of a voltage, and further comprising a resistive element having a first terminal coupled to the second terminal and having a second terminal coupled to the first gate.

3. The electronic device of claim 2, wherein the second terminal of the resistive element is further coupled to the channel-forming region.

4. The electronic device of claim 1, wherein the drain region and the extension region are separated from each other, under the second gate, by a separation region.

5. The electronic device of claim 4, wherein the separation region is one of non-doped or doped with a conductivity type opposite to a conductivity type of the drain region.

6. The electronic device of claim 4, wherein the drain region and the extension region comprise two portions extending from opposite sides of the separation region.

7. The electronic device of claim 6, wherein the two portions of the drain region and the extension region are coupled together.

8. The electronic device of claim 4, wherein the separation region and the channel-forming region are coupled together.

9. The electronic device of claim 1, wherein the drain region, the extension region, and the source region of the first MOS transistor are doped with a first conductivity type, the channel-forming region being one of non-doped or doped with a second conductivity type opposite to the first conductivity type.

10. The electronic device of claim 1, wherein the source region, drain region, and channel-forming region all extend in a semiconductor layer resting on an insulating layer.

11. The electronic device of claim 1, wherein the second gate is located over a only a portion of the extension region.

12. The electronic device of claim 1, further comprising a second MOS transistor connected in parallel with said first MOS transistor.

13. The electronic device of claim 12, wherein a drain region and a source region and a gate of the second MOS transistor are respectively coupled to the drain region, the source region and the first and second gates of the first MOS transistor.

14. The electronic device of claim 13, wherein a body region of the second MOS transistor is coupled to a body region of the first MOS transistor.

15. An electronic device, comprising:
a MOS transistor having a source region, a drain region and a channel-forming region located between the source and drain regions;
wherein the drain region comprises a first drain portion and a second drain portion, said first drain portion located adjacent the channel-forming region and said second drain portion separated from the channel-forming region by the first drain portion;
a first gate extending over the channel-forming region; and
a second gate extending over the second drain portion;
wherein the second gate is electrically connected to the first gate.

16. The electronic device of claim 15, wherein the first gate and second gate are electrically connected to a body region formed by the channel-forming region.

17. The electronic device of claim 15, wherein the source region is electrically coupled to a first power supply node and the first and second drain regions are electrically coupled to a second power supply node.

18. The electronic device of claim 17, further comprising a resistor having a first terminal electrically coupled to the first and second gates and a second terminal electrically coupled to the first power supply node.

19. An electronic device, comprising:
a MOS transistor having a source region doped with a first conductivity type, a drain region doped with the first conductivity type, a channel-forming region located between the source and drain regions, an extended drain region doped with the first conductivity type; and a separation region located between the extended drain region source and the drain region;
a first gate extending over the channel-forming region; and
a second gate extending over the separation region;
wherein the second gate is electrically connected to the first gate.

20. The electronic device of claim 19, wherein the channel-forming region and the separation region are doped with a second conductivity type opposite the first conductivity type.

21. The electronic device of claim 19, wherein the first gate and second gate are electrically connected to a first body region formed by the channel-forming region.

22. The electronic device of claim 21, wherein the first gate and second gate are electrically connected to a second body region formed by the separation region.

23. The electronic device of claim 19, wherein the source region is electrically coupled to a first power supply node and the drain region and extended drain region are electrically coupled to a second power supply node.

24. The electronic device of claim 23, further comprising a resistor having a first terminal electrically coupled to the first and second gates and a second terminal electrically coupled to the first power supply node.
